(19) United States
(12) Patent Application Publication
(10) Pub. No.: US 2002/0179953 A1
(43) Pub. Date: Dec. 5, 2002

(54) Method of manufacturing a multi-wall cylindrical capacitor

(76) Inventor: Masahiro Yoshida, Tokyo (JP)

Correspondence Address: VOLENTINE FRANCOS, PLLC, Suite 150, 12200 Sunrise Valley Drive, Reston, VA, 20191, US

(21) Appl. No.: 10/160,266

(22) Filed: Jun. 4, 2002

(30) Foreign Application Priority Data
Jun. 4, 2001 (JP) 168666/2001

(51) Int. Cl. H01L 29/94

(52) U.S. Cl. 257/303

(57) ABSTRACT

A storage electrode of a multi-wall cylindrical capacitor includes an inner cylindrical portion having a first convex electrode region and an outer cylindrical portion having a second convex electrode region which is smaller and more sparse than the first convex electrode region. Therefore, a short between adjoining the storage electrodes can be inhibited.

### CROSS REFERENCE TO RELATED APPLICATIONS

The present application claims priority under 35 U.S.C. 119 to Japanese Patent Application No. 2001-168666, filed Jun. 4, 2001, which is herein incorporated by reference in its entirely for all purposes.

### BACKGROUND OF THE INVENTION

1. Field of the Invention

The present invention relates to a method of manufacturing a multi-wall cylindrical capacitor, in particular, to the structure of a storage capacitor in a semiconductor device such as a semiconductor memory device, generally referred to as a dynamic random access memory (DRAM), and to a method of manufacturing such a storage capacitor.

2. Description of the Related Art

Recently, with the enhancement of the integration level in a memory cell of a DRAM, the chip area for the DRAM decreases year to year. A hemi spherical grained (HSG) structure is one of conventional methods of manufacturing a capacitor. In the HSG method, convex portions are formed on a surface of a storage electrode having a cylinder structure. On the other hand, the surface of the storage electrode becomes rough due to the HSG method. As a result, the area and the capacitance of the capacitor increases. Specifically, a central core which later would become the convex portion is formed on an amorphous silicon layer. Next, an annealing is performed in a high vacuum atmosphere. At this time, a temperature of the annealing is from 600° C. to 620° C. Such the capacitor structure is called a cylinder type capacitor or a cylinder type stacked capacitor.

FIGS. 10(a) through 10(c), FIGS. 11(a) through 11(c) and FIGS. 12(a) and 12(b) are cross-sectional views for explaining a method of manufacturing a conventional multi-wall cylindrical capacitor. As shown in FIG. 10(a), field oxide regions 2 are formed in a semiconductor substrate 1, for example, a silicon substrate. Next, a first interlayer insulating film 3, a second interlayer insulating film 4 and a nitride film 5 are formed over the semiconductor substrate 1 in order.

Next, as shown in FIG. 10(b), contact holes 6 which go through the first and second interlayer insulating films 3 and 4 and the nitride film 5 are formed by a photolithography and etching method.

Next, as shown in FIG. 10(c), plugs 7 (e.g., poly-silicon plugs) are formed in the contact holes 6.

Next, as shown in FIG. 11(a), after an oxide film 8 (or a boron-phospho silicate glass (BPSG) film 8) is formed, openings 9 which expose a top of the plugs 7 are formed by the photolithography and etching method. Storage electrodes are formed later in such the openings 9.

Next, as shown in FIG. 11(b), a poly-silicon film 10, that later would be patterned into the storage electrode, is formed. Then, an impurity ion (e.g., a phosphorus ion) is implanted into the poly-silicon film 10. A phosphorus ion concentration of the poly-silicon film 10 is equal to or less than 1E20 cm⁻³. Next, protection regions 11 which protect an inner wall of the poly-silicon film 10 locating in the openings 109 are formed. In this specification, the phosphorus ion concentration indicates the number of the phosphorus ions per 1 cm³. For example, “1×10²⁰ atoms/cm³” means that there are 1×10²⁰ atoms phosphorus ion in 1 cm³ of poly-silicon 10.

Next, as shown in FIG. 11(c), the poly-silicon film 10 outside of the openings 9 is removed, and then the film 8 and protection regions 11 are removed. As a result, storage electrodes 10 having a cylinder structure are formed.

Next, the above mentioned HSG method is performed. Specifically, an annealing is performed after central cores which later would be convex portions (grains) are formed on a surface of the storage electrodes 10 having a cylinder structure. On the other hand, the surface of the storage electrodes 10 having a cylinder structure becomes rough due to the HSG method. As a result, as shown in FIG. 12(a), the storage electrodes 10 having a cylinder structure and a rough surface are formed.

Next, an impurity ion, for example, a phosphorus ion is implanted into the storage electrodes 10 for increasing a conductivity of the storage electrodes 10. Then, as shown in FIG. 12(b), a nitride film 12 as a capacitor insulating film is formed on the surface of the storage electrodes 10, and then a poly-silicon film 13 which is a cell-plate electrode is formed. As a result, the cylinder type capacitor is complete.

However, there is a problem inherent in the conventional multi-wall cylindrical capacitor. A short between adjoining the storage electrodes occurs, with the enhancement of the integration level in a memory cell of a DRAM.

### SUMMARY OF THE INVENTION

In a method of manufacturing a multi-wall cylindrical capacitor according to the present invention, a first electrode that includes an outer cylindrical portion having a first impurity ion concentration and an inner cylindrical portion having a second impurity ion concentration which is lower than the first impurity ion concentration is formed, and a first convex electrode region on a surface of the inner cylindrical portion and a second convex electrode region that is smaller than the first convex electrode region on a surface of the outer cylindrical portion are formed.

According to the present invention, a short between adjoining the storage electrodes can be inhibited.

The above and further novel features of the invention will more fully apparent from the following detailed description, appended claims and accompanying drawings.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIGS. 1(a) through 1(c), FIGS. 2(a) through 2(c) and FIGS. 3(a) and 3(b) are cross-sectional views showing a method of manufacturing a multi-wall cylindrical capacitor according to a first preferred embodiment of the present invention;

FIGS. 4(a) through 4(c) and FIGS. 5(a) and 5(b) are cross-sectional views showing a method of manufacturing a multi-wall cylindrical capacitor according to a second preferred embodiment of the present invention;

FIGS. 6(a) through 6(c) and FIGS. 7(a) through 7(c) are cross-sectional views showing a method of manufacturing a multi-wall cylindrical capacitor according to a third preferred embodiment of the present invention;

FIGS. 8(a) through 8(c) and FIGS. 9(a) through 9(c) are cross-sectional views showing a method of manufacturing a multi-wall cylindrical capacitor according to a fourth preferred embodiment of the present invention; and

FIGS. 10(a) through 10(c), FIGS. 11(a) through 11(c) and FIGS. 12(a) and 12(b) are cross-sectional views showing a method of manufacturing a conventional multi-wall cylindrical capacitor.

### DETAILED DESCRIPTION OF THE PREFERRED EMBODIMENTS

Preferred embodiments of the present invention will hereinafter be described in detail with reference to the accompanying drawings. The drawings used for this description typically illustrate major characteristic parts in order that the present invention will be easily understood.

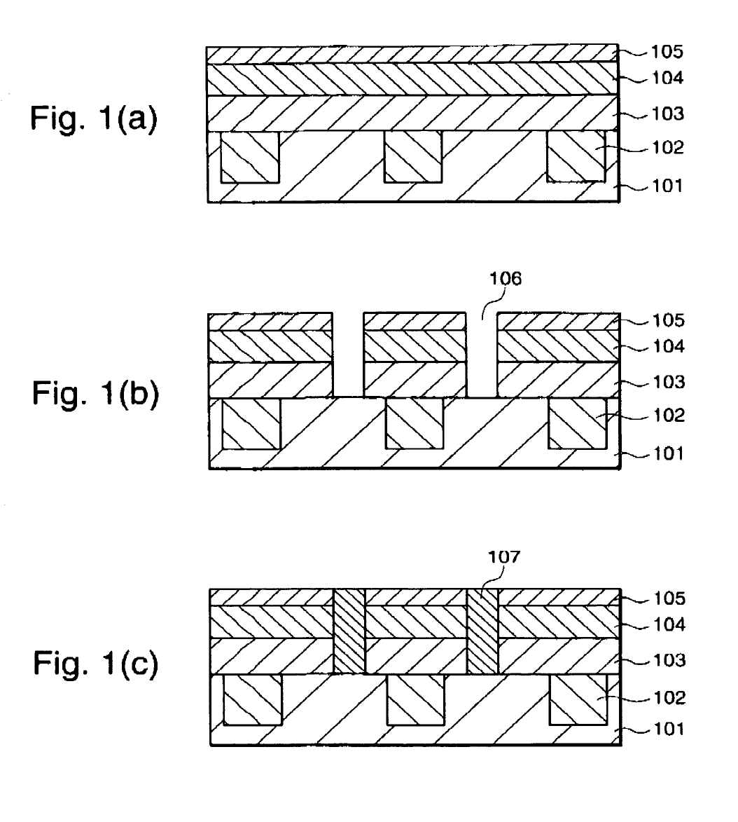

FIGS. 1(a) through 1(c), FIGS. 2(a) through 2(c) and FIGS. 3(a) and 3(b) are cross-sectional views showing a method of manufacturing a multi-wall cylindrical capacitor according to a first preferred embodiment of the present invention.

As shown in FIG. 1(a), field oxide regions 102 are formed in a semiconductor substrate 101, for example, a silicon, by a shallow trench isolation method (an STI method). A thickness of the field oxide regions 102 is from 3000 Å to 5000 Å. Then, a first interlayer isolation film 103 (e.g., an oxide film, a BPSG film) is formed over the semiconductor substrate 1, by a chemical vapor deposition method (a CVD method). A thickness of the first interlayer insulating film 103 is from 2000 Å to 5000 Å. Then, a second interlayer insulating film 104 (e.g., an oxide film, a BPSG film) is formed on the fist interlayer insulating film 103, by the CVD method. A thickness of the second interlayer insulating film 104 is from 2000 Å to 5000 Å. Next, a nitride film 105 that is subsequently used as an etching stopper is formed on the second interlayer insulating film 104 by the CVD. A thickness of the nitride film 105 is from 500 Å to 2000 Å.

Next, as shown in FIG. 1(b), contact holes which pass through the first and second interlayer insulating films 103 and 104 and the nitride film 105 are formed by a photolithography and etching method.

Next, a poly-silicon film which buries in the contact holes 106 is formed by the CVD method. At this time, a thickness of the poly-silicon film is from 1000 Å to 5000 Å. Then, an impurity ion, for example, a phosphorus ion is implanted into the poly-silicon film for rising a conductivity of the poly-silicon film. Then, an etch-back method is performed to remove the poly-silicon film without in the contact holes 106. As a result, as shown in FIG. 1(c), poly-silicon plugs 107 are formed.

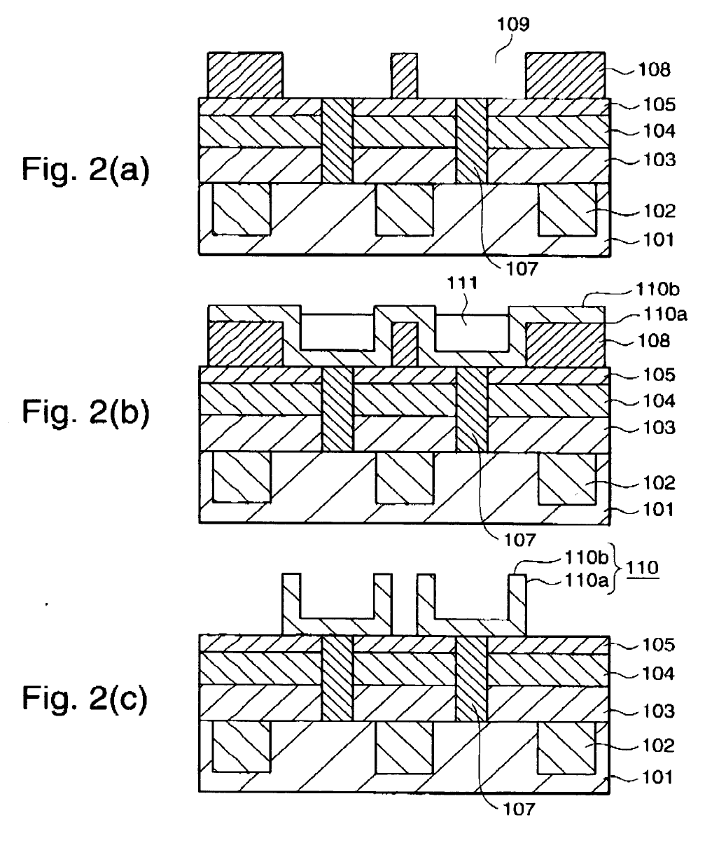

Next, an oxide film 108 (or a BPSG film 108) is formed by the CVD method. A thickness of the film 108 is from 2000 Å to 8000 Å. Then, as shown in FIG. 2(a), openings 109 which expose a top of the poly-silicon plugs 107 are formed by the photolithography and etching method. Storage electrodes are formed later in such the openings 109. The film 108 is called a sacrifice film because the film 108 is removed after the storage electrodes are formed.

Next, as shown in FIG. 2(b), a first poly-silicon film 110a is formed by the CVD. A thickness of the first poly-silicon film 110a is from 200 Å to 400 Å. Then, an impurity ion (e.g., a phosphorus ion) is implanted into the first poly-silicon film 110a. A phosphorus ion concentration of the first poly-silicon film 110a is from 3E20 cm⁻³ to 4E20 cm⁻³. Next, a second poly-silicon film 110b is formed by the CVD on the first poly-silicon film 110a. A thickness of the second poly-silicon film 110b is from 400 Å to 600 Å. Then, an impurity ion (e.g., a phosphorus ion) is implanted into the second poly-silicon film 110b. A phosphorus ion concentration of the second poly-silicon film 110b is equal to or less than 1E20 cm⁻³. Next, protection regions 111 which protect an inner wall of the poly-silicon film 110b locating in the openings 109 are formed.

Next, the first and second poly-silicon films 110a and 110b outside of the openings 109 are removed by the etch-back method, and then the film 108 and the protection film 111 are removed. As a result, as shown in FIG. 2(c), storage electrodes 110 having a cylinder structure that consists of the first and second poly-silicon film 110a and 110b are formed.

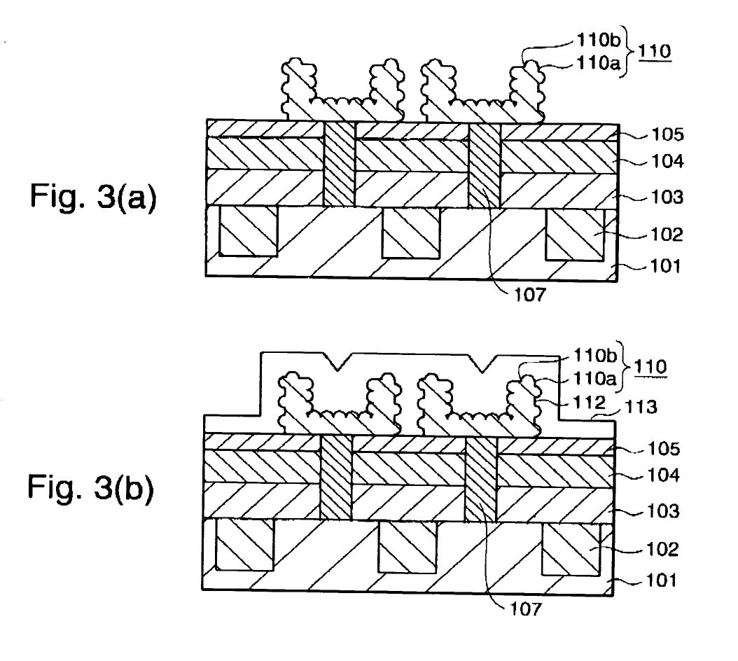

Next, the above mentioned HSG method is performed. Specifically, an annealing is performed after central cores which later would be convex portions (grains) having a hemisphere structure are formed on a surface of the storage electrodes 110 having a cylinder structure. On the other hand, the surface of the storage electrodes 110 having a cylinder structure changes to be rough due to the HSG method. Since a phosphorus ion concentration of the outer cylindrical portions 110a of the storage electrodes 110 is higher than that of the inner cylindrical portions 110b of the same 110, as shown in FIG. 3(a), convex portions (grains) having a hemisphere structure which is formed in the outer cylindrical portions 110a of the storage electrodes 110 are smaller and more sparse than that is formed in the inner cylindrical portions 110b of the same 110.

Next, an impurity ion, for example, a phosphorus ion is implanted into the storage electrodes 110 for increasing the conductivity of the storage electrodes 110. Then, as shown in FIG. 3(b), a nitride film 112 as a capacitor insulating film is formed on the surface of the storage electrodes 110, and then a poly-silicon film 113 which is a cell-plate electrode is formed. As a result, the cylinder type capacitor is complete.

According to the first preferred embodiment of the present invention, since a phosphorus ion concentration of the outer cylindrical portions 110a of the storage electrodes 110 is higher than that of the inner cylindrical portions 110b of the same 110, convex portions (grains) having a hemisphere structure which are formed in the outer cylindrical portions 110a of the storage electrodes 110 are smaller and more sparse than those are formed in the inner cylindrical portions 110b of the same 110. Therefore, a short between adjoining the storage electrodes 110 can be inhibited. As a result, a quality of a memory cell of the DRAM can be effectively improved.

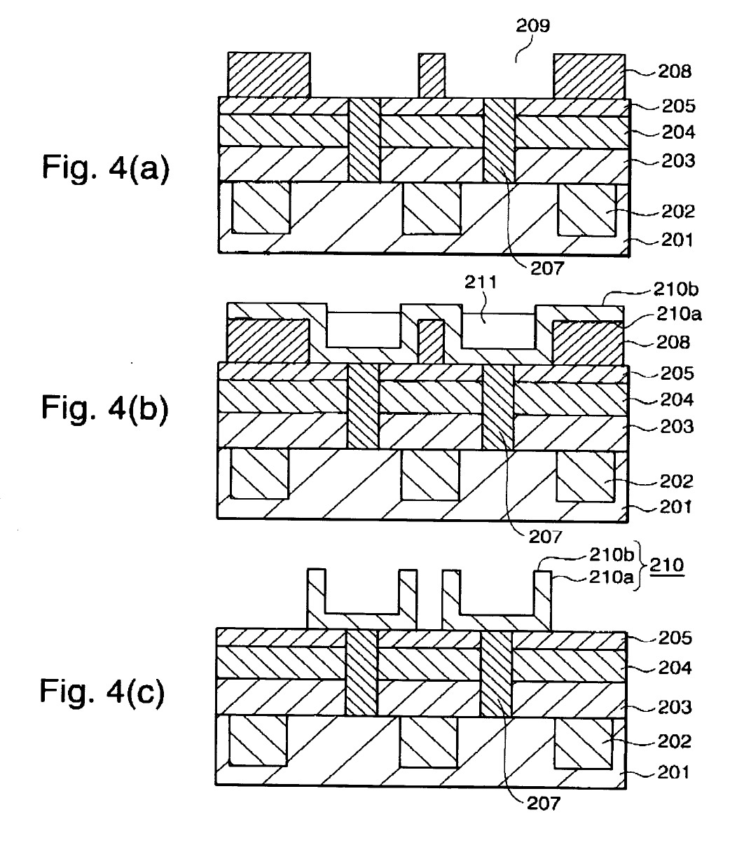

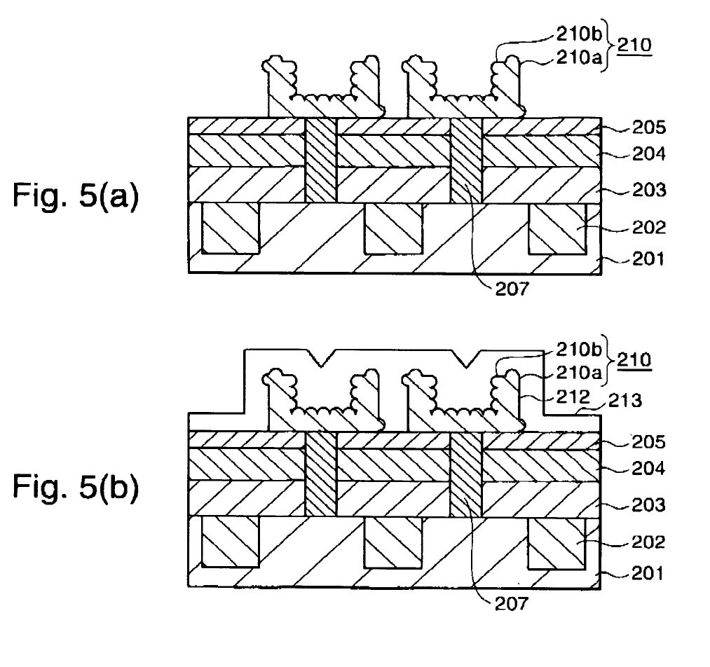

FIGS. 4(a) through 4(c) and FIGS. 5(a) and 5(b) are cross-sectional views showing the method of manufacturing a multi-wall cylindrical capacitor according to a second preferred embodiment of the present invention. The second preferred embodiment includes the same process steps as shown in FIGS. 1(a) through 1(c) of the first preferred embodiment.

After poly-silicon plugs 207 are formed (similar to FIG. 1(c)), an oxide film 208 (or a BPSG film 208) is formed by the CVD method. A thickness of the film 208 is from 2000 Å to 8000 Å. Then, as shown in FIG. 4(a), openings 209 which expose a top of the poly-silicon plugs 207 are formed by the photolithography and etching method. Storage electrodes are formed later in such the openings 209.

Next, as shown in FIG. 4(b), a first poly-silicon film 210a is formed by the CVD. A thickness of the first poly-silicon film 210a is from 200 Å to 400 Å. Then, an impurity ion (e.g., a phosphorus ion) is implanted into the first poly-silicon film 210a. A phosphorus ion concentration of the first poly-silicon film 210a is from 4E20 cm⁻³ to 5E20 cm⁻³, in the second preferred embodiment is about 5E20 cm⁻³. Next, a second poly-silicon film 210b is formed by the CVD on the first poly-silicon film 210a. A thickness of the second poly-silicon film 110b is from 400 Å to 600 Å. Then, an impurity ion (e.g., a phosphorus ion) is implanted into the second poly-silicon film 210b. A phosphorus ion concentration of the second poly-silicon film 210b is equal to or less than 1E20 cm⁻³. Next, protection regions 211 which protect an inner wall of the poly-silicon film 210b locating in the openings 209 are formed. In the second preferred embodiment, a phosphorus ion concentration of the first poly-silicon film 210a is higher than that of the first poly-silicon film 110a of the first preferred embodiment.

Next, the first and second poly-silicon films 210a and 210b outside of the openings 209 are removed by the etch-back method, and then the film 208 and the protection film 211 are removed. As a result, as shown in FIG. 4(c), storage electrodes 210 having a cylinder structure that consists of the first and second poly-silicon film 210a and 210b are formed.

Next, the above mentioned HSG method is performed. Specifically, an annealing is performed after central cores which later would be convex portions (grains) having a hemisphere structure are formed on a surface of the storage electrodes 210 having a cylinder structure. On the other hand, the surface of the storage electrodes 210 having a cylinder structure becomes rough due to the HSG method. Since a phosphorus ion concentration of the outer cylindrical portions 210a of the storage electrodes 210 is higher than that of the inner cylindrical portions 210b of the same 210, as shown in FIG. 5(a), convex portions (grains) having a hemisphere structure which are formed in the outer cylindrical portions 210a of the storage electrodes 210 are smaller and more sparse than that is formed in the inner cylindrical portions 210b of the same 210. Specifically, since the phosphorus ion concentration of the outer cylindrical portions 210a is very high, there are hardly convex portions (grains) having a hemisphere structure in the outer cylindrical portions 210a.

Next, an annealing is performed to increase the conductivity of the storage electrodes 210. As a result, the impurity ion (the phosphorus ion) in the outer cylindrical portions 210a is diffused into the inner cylindrical portions 210b. Then, as shown in FIG. 5(b), a nitride film 212 as a capacitor insulating film is formed on the surface of the storage electrodes 210, and then a poly-silicon film 213 which is a cell-plate electrode is formed. As a result, the cylinder type capacitor is complete.

According to the second preferred embodiment of the present invention, since convex portions (grains) having a hemisphere structure which are formed in the outer cylindrical portions 210a of the storage electrodes 210 are extremely sparse, a short between adjoining the storage electrodes 210 can be inhibited. As a result, a quality of a memory cell of the DRAM can be effectively improved. Furthermore, a process step for rising a conductivity of the storage electrodes 210 can be simplified.

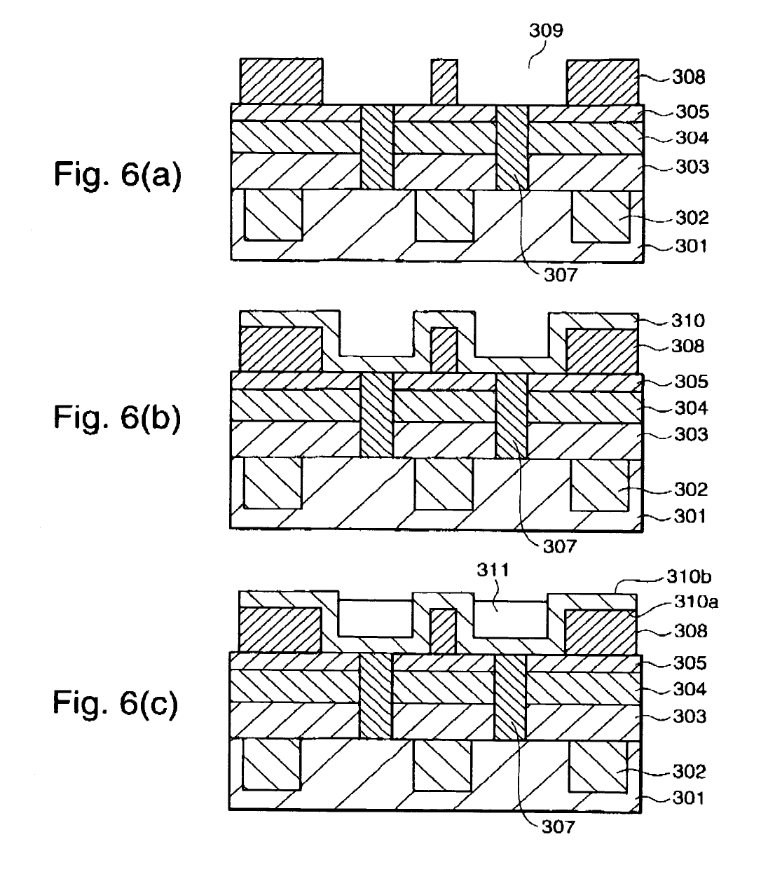

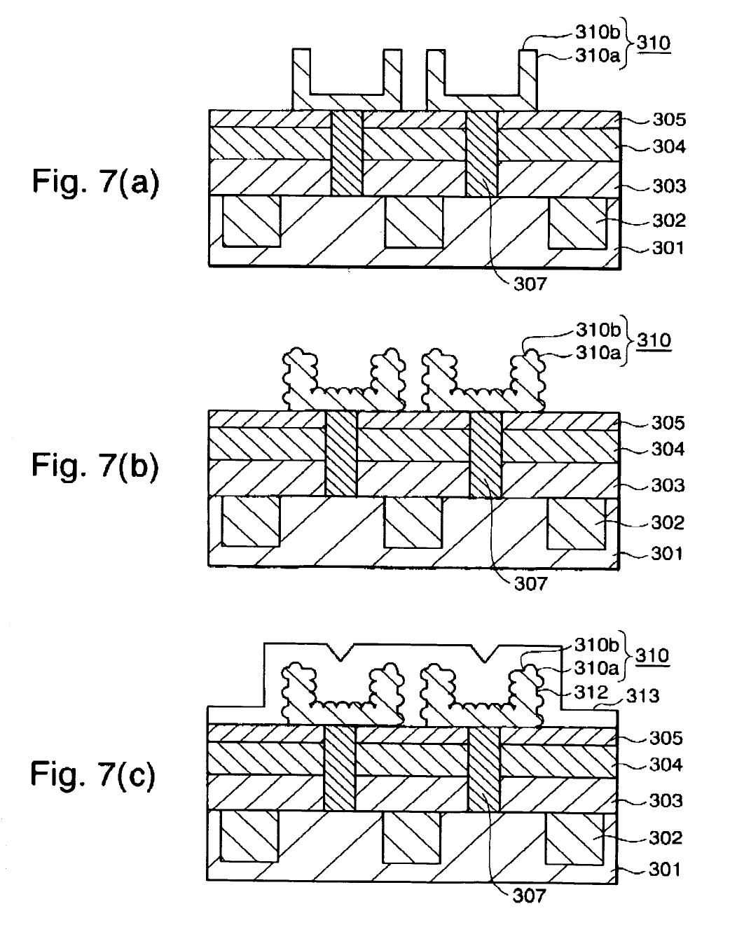

FIGS. 6(a) through 6(c) and FIGS. 7(a) through 7(c) are cross-sectional views showing the method of manufacturing a multi-wall cylindrical capacitor according to a third preferred embodiment of the present invention. The third preferred embodiment includes the same process steps as shown in FIGS. 1(a) through 1(c) of the first preferred embodiment.

After poly-silicon plugs 307 are formed (similar to FIG. 1(c)), a phosphorus silicate glass film 308 (a PSG film 308) is formed by the CVD method. A thickness of the PSG film 308 is from 2000 Å to 8000 Å. An impurity ion, for example, a phosphorus ion is implanted into the PSG film 308. A phosphorus ion concentration of the PSG film 308 is from 3E20 cm⁻³ to 4E20 cm⁻³, in the third preferred embodiment is about 3E20 cm⁻³. Then, as shown in FIG. 6(a), openings 309 which expose a top of the poly-silicon plugs 307 are formed by the photolithography and etching method. Storage electrodes are formed later in such the openings 309.

Next, as shown in FIG. 6(b), a poly-silicon film 310 is formed by the CVD on the PSG film 308. A thickness of the poly-silicon film 310 is from 600 Å to 1000 Å. Then, an impurity ion (e.g., a phosphorus ion) is implanted into the poly-silicon film 310. A phosphorus ion concentration of the poly-silicon film 310 is equal to or less than 1E20 cm³.

Next, as shown in FIG. 6(c), an outer layer 310a and an inner layer 310b are formed in the poly-silicon film 310 by an annealing which is performed at a temperature of 800˜900 in a nitride atmosphere. Since a phosphorus ion in the PSG film 308 is diffused into the outer layer 310a adjoining the PSG film 308, a phosphorus ion concentration of the outer layer 310a is higher than that of the inner layer 310b. At this time, the phosphorus ion concentration of the outer layer 310a is about 3E20 cm⁻³ because the phosphorus ion concentration of the PSG film 308 is about 3E20 cm⁻³. Then, protection regions 311 which protect an inner wall of the poly-silicon film 310 locating in the openings 309 are formed.

Next, the poly-silicon film 310 (the outer and inner layers 310a and 310b) outside of the openings 309 are removed by the etch-back method, and then the PSG film 308 and the protection film 311 are removed. As a result, as shown in FIG. 7(a), storage electrodes 310 having a cylinder structure that consists of the outer and inner cylindrical portions 310a and 310b are formed.

Next, the above mentioned HSG method is performed. Specifically, an annealing is performed after central cores which later would be convex portions (grains) having a hemisphere structure are formed on a surface of the storage electrodes 310 having a cylinder structure. On the other hands, the surface of the storage electrodes 310 having a cylinder structure becomes rough due to the HSG method. Since a phosphorus ion concentration of the outer cylindrical portions 310a of the storage electrodes 310 is higher than that of the inner cylindrical portions 310b of the same 310, as shown in FIG. 7(b), convex portions (grains) having a hemisphere structure which are formed in the outer cylindrical portions 310a of the storage electrodes 310 are smaller and more sparse than that is formed in the inner cylindrical portions 310b of the same 310.

Next, an impurity ion, for example, a phosphorus ion is implanted into the storage electrodes 310 for increasing the conductivity of the storage electrodes 310. Then, as shown in FIG. 7(c), a nitride film 312 as a capacitor insulating film is formed on the surface of the storage electrodes 310, and then a poly-silicon film 313 which is a cell-plate electrode is formed. As a result, the cylinder type capacitor is complete.

According to the third preferred embodiment of the present invention, since a phosphorus ion concentration of the outer cylindrical portions 310a of the storage electrodes 310 is higher than that of the inner cylindrical portions 310b of the same 310, convex portions (grains) having a hemisphere structure which are formed in the outer cylindrical portions 310a of the storage electrodes 310 are smaller and more sparse than that is formed in the inner cylindrical portions 310b of the same 310. Therefore, a short between adjoining the storage electrodes 310 can be inhibited. As a result, a quality of a memory cell of the DRAM can be effectively improved. Furthermore, a process step for forming a ply-silicon film can be abbreviated.

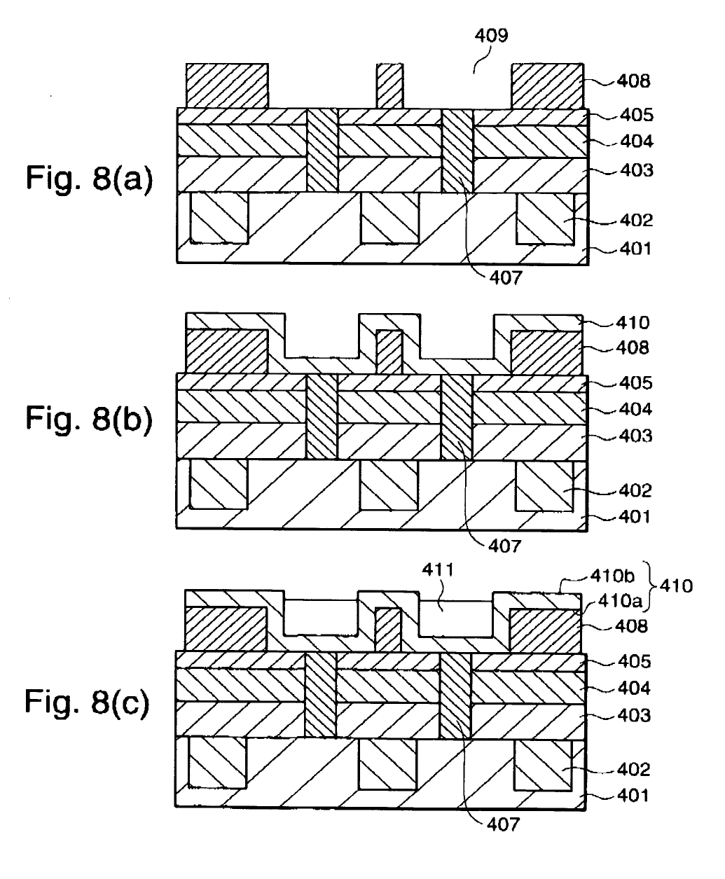

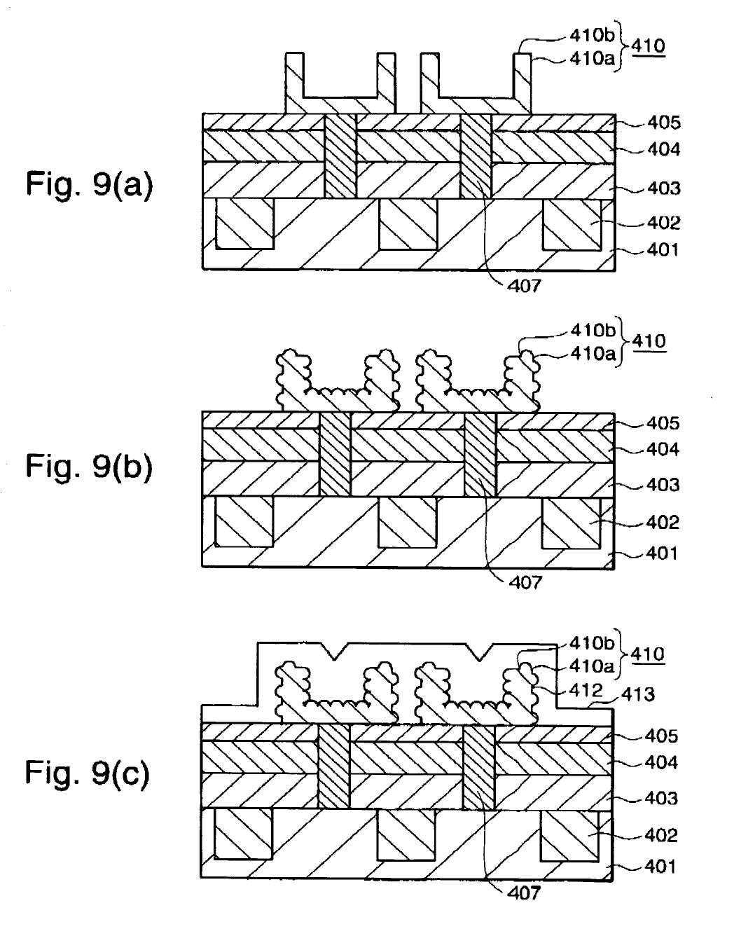

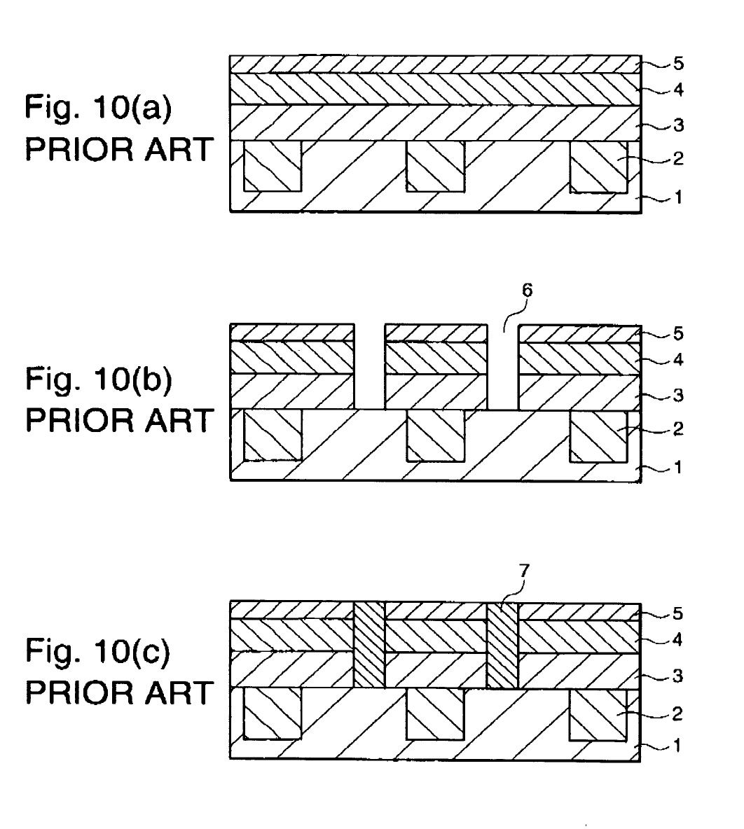

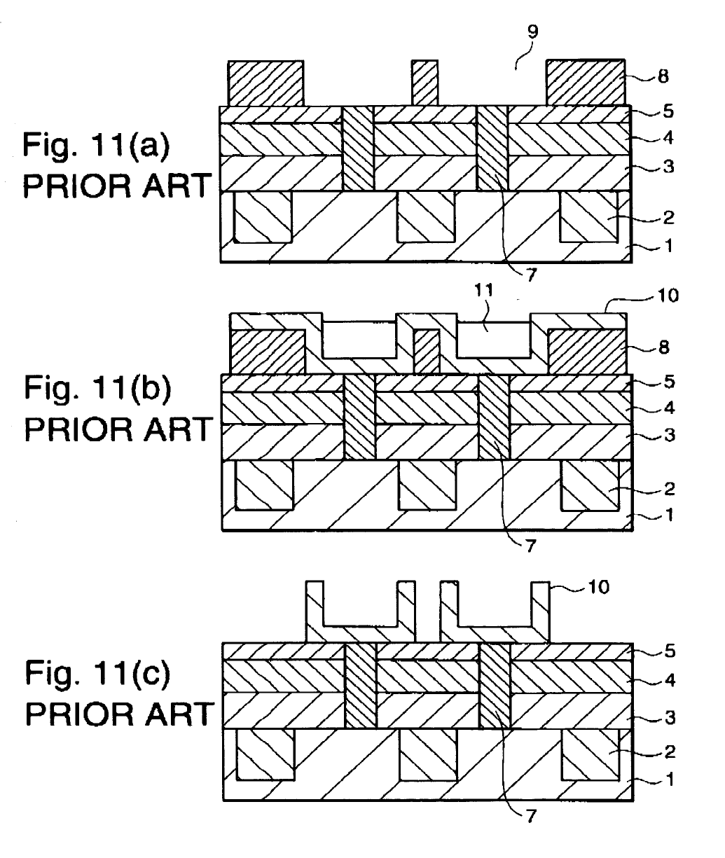

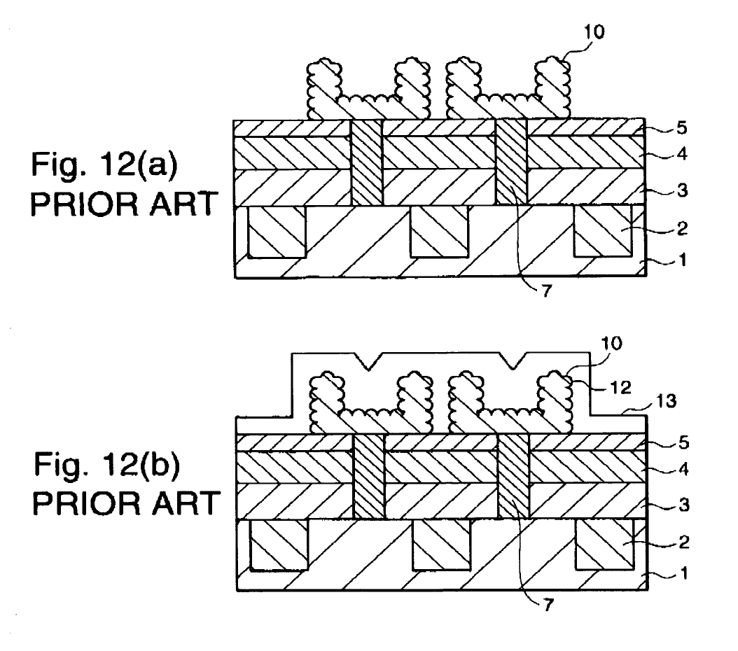

FIGS. 8(a) through 8(c) and FIGS. 9(a) through 9(c) are cross-sectional views showing the method of manufacturing a multi-wall cylindrical capacitor according to a fourth preferred embodiment of the present invention. The fourth preferred embodiment includes the same process steps as shown in FIGS. 1(a) through 1(c) of the first preferred embodiment.

After poly-silicon plugs 407 are formed (similar to FIG. 1(c)), an oxide film 408 is formed by the CVD method. A thickness of the oxide film 308 is from 2000 Å to 8000 Å. Then, as shown in FIG. 8(a), openings 409 which expose a top of the poly-silicon plugs 407 are formed by the photolithography and etching method. Storage electrodes are formed later in such the openings 409. Next, a phosphorus ion is doped into the oxide film 408 by an annealing in a PH₄ atmosphere. A phosphorus ion concentration of the doped oxide film 408 is from 3E20 cm⁻³ to 4E20 cm⁻³, in the fourth preferred embodiment is about 3E20 cm⁻³.

Next, as shown in FIG. 8(b), a poly-silicon film 410 is formed by the CVD on the doped oxide film 408. A thickness of the poly-silicon film 410 is from 600 Å to 1000 Å. Then, an impurity ion (e.g., a phosphorus ion) is implanted into the poly-silicon film 410. A phosphorus ion concentration of the poly-silicon film 410 is equal to less than 1E20 cm⁻³.

Next, as shown in FIG. 8(c), an outer layer 410a and an inner layer 410b are formed in the poly-silicon film 410 by an annealing which is performed at a temperature of 800˜900 in a nitride atmosphere. Since a phosphorus ion in the doped oxide film 408 is diffused into the outer layer 410a adjoining the doped oxide film 408, a phosphorus ion concentration of the outer layer 410a is higher than that of the inner layer 410b. At this time, the phosphorus ion concentration of the outer layer 410a is about 3E20 cm⁻³ because the phosphorus ion concentration of the doped oxide film 408 is about 3E20 cm⁻³. Then, protection regions 411 which protect an inner wall of the poly-silicon film 410 locating in the openings 409 are formed.

Next, the poly-silicon film 410 (the outer and inner layers 410a and 410b) outside of the openings 409 are removed by the etch-back method, and then the doped oxide film 408 and the protection film 411 are removed. As a result, as shown in FIG. 9(a), storage electrodes 410 having a cylinder structure that consists of the outer and inner cylindrical portions 410a and 410b are formed.

Next, the above mentioned HSG method is performed. Specifically, an annealing is performed after central cores which later would be convex portions (grains) having a hemisphere structure are formed on a surface of the storage electrodes 410 having a cylinder structure. On the other hands, the surface of the storage electrodes 410 having a cylinder structure becomes rough due to the HGS method. Since a phosphorus ion concentration of the outer cylindrical portions 410a of the storage electrodes 410 is higher than that of the inner cylindrical portions 410b of the same 410, as shown in FIG. 9(b), convex portions (grains) having a hemisphere structure which are formed in the outer cylindrical portions 410a of the storage electrodes 410 are smaller and more sparse than that is formed in the inner cylindrical portions 410b of the same 410.

Next, an impurity ion, for example, a phosphorus ion is implanted into the storage electrodes 410 for increasing the conductivity of the storage electrodes 410. Then, as shown in FIG. 9(c), a nitride film 412 as a capacitor insulating film is formed on the surface of the storage electrodes 410, and then a poly-silicon film 413 which is a cell-plate electrode is formed. As a result, the cylinder type capacitor is complete.

According to the fourth preferred embodiment of the present invention, since a phosphorus ion concentration of the outer cylindrical portions 410a of the storage electrodes 410 is higher than that of the inner cylindrical portions 410b of the same 410, convex portions (grains) having a hemisphere structure which are formed in the outer cylindrical portions 410a of the storage electrodes 410 are smaller and more sparse than that is formed in the inner cylindrical portions 410b of the same 410. Therefore, a short between adjoining the storage electrodes 410 can be inhibited. As a result, a quality of a memory cell of the DRAM can be effectively improved.

While the third preferred embodiment of the present invention presents an example in which the phosphorus ion concentration of the PSG film is from 3E20 cm⁻³ to 4E20 cm⁻³, the invention is not limited to this, and may instead be from 4E20 cm⁻³ to 5E20 cm⁻³. Similarly, while the fourth preferred embodiment of the present invention presents an example in which the phosphorus ion concentration of the doped oxide film is from 3E20 cm⁻³ to 4E20 cm⁻³, the invention is not limited to this, and may instead be from 4E20 cm⁻³ to 5E20 cm⁻³.

As described above, according to the multi-wall cylindrical capacitor and the manufacturing the same of the present, since convex portions (grains) having a hemisphere structure which are formed in the outer cylindrical portions of the storage electrode of the capacitor are smaller and more sparse than those are formed in the inner cylindrical portions of the same. Therefore, a short between adjoining the capacitors can be inhibited. As a result, a quality of a memory cell of the DRAM having such the capacitor can be effectively improved.

The present invention has been described with reference to illustrative embodiments, however, this invention must not be considered to be confined only to the embodiments illustrated. Various modifications and changes of these illustrative embodiments and the other embodiments of the present invention will become apparent to those skilled in the art with reference to the description of the present invention. It is therefore contemplated that the appended claims will cover any such modifications or embodiments as fall within the true scope of the invention.

What is claimed is:

1. A method of manufacturing a multi-wall cylindrical capacitor comprising:
forming first and second insulating films in order, over a semiconductor substrate;
forming a contact plug in a contact hole that pass through the first and second insulating films;
forming a first electrode connecting to the contact plug that includes an outer cylindrical portion having a first impurity ion concentration, and an inner cylindrical portion having a second impurity ion concentration that is higher than the first impurity ion concentration;
forming a first convex electrode region on a surface of the inner cylindrical portion, and a second convex electrode region that is smaller than the first convex electrode region on a surface of the outer cylindrical portion;
forming a third insulating film over the first electrode; and
forming a second electrode over the third insulating film.

2. The method of manufacturing the multi-wall cylindrical capacitor according to claim 1, wherein the first impurity ion concentration is from 3E20 cm⁻³ to 4E20 cm⁻³, and the second impurity ion concentration is equal to or less than 1E20 cm⁻³.

3. The method of manufacturing the multi-wall cylindrical capacitor according to claim 1, wherein the first impurity ion concentration is from 4E20 cm⁻³ to 5E20 cm⁻³, and the second impurity ion concentration is equal to or less than 1E20 cm⁻³.

4. A method of manufacturing a multi-wall cylindrical capacitor comprising:
forming first and second insulating films, in order, over a semiconductor substrate;
forming a contact plug in a contact hole which goes through the first and second insulating films;
forming a third insulating film being doped with an impurity ion over the first and second insulating films, wherein the third insulating film has an opening that exposes a top of the contact plug, and has a first impurity ion concentration;
forming a conductive film having a second impurity ion concentration that is lower than the first impurity ion concentration, over the third insulating film;
forming a first electrode that includes an outer cylindrical portion having a third impurity ion concentration that is substantially the same as the first impurity ion concentration, and an inner cylindrical portion having the second impurity ion concentration that is substantially equal to the second impurity ion concentration, by annealing the third insulating film and the conductive film, and removing the third insulating film and the conductive film outside of the opening;
forming a first convex electrode region on a surface of the inner cylindrical portion, and a second convex electrode region that is smaller than the first convex electrode region on a surface of the outer cylindrical portion;
forming a fourth insulating film over the first electrode; and
forming a second electrode over the forth insulating film.

5. The method of manufacturing the multi-wall cylindrical capacitor according to claim 4, wherein the third insulating film is a phosphorus silicate glass film, and the impurity ion is a phosphorus ion.

6. The method of manufacturing the multi-wall cylindrical capacitor according to claim 4, wherein the first impurity ion concentration is from 3E20 cm⁻³ to 4E20 cm⁻³, and the second impurity ion concentration is equal to or less than 1E20 cm⁻³.

7. The method of manufacturing the multi-wall cylindrical capacitor according to claim 4, wherein the first impurity ion concentration is from 4E20 cm⁻³ to 5E20 cm⁻³, and the second impurity ion concentration is equal to or less than 1E20 cm⁻³.

8. The method of manufacturing the multi-wall cylindrical capacitor according to claim 5, wherein the annealing is performed in a nitride atmosphere.

9. A method of manufacturing a multi-wall cylindrical capacitor comprising:
forming first and second insulating films, in order, over a semiconductor substrate;
forming a contact plug in a contact hole that pass through the first and second insulating films;
forming a third insulating film over the first and second insulating films, wherein the third insulating film has an opening that exposes a top of the contact plug;
doping an impurity ion into the third insulating film, wherein the third insulating film has the first impurity ion concentration;
forming a conductive film having a second impurity ion concentration that is lower than the first impurity ion concentration, over the third insulating film;
forming a first electrode that includes an outer cylindrical portion having a third impurity ion concentration that is substantially equal to the first impurity ion concentration, and an inner cylindrical portion having a fourth impurity ion concentration that is substantially equal to the second impurity ion concentration, by annealing the third insulating film and the conductive film, and removing the third insulating film and the conductive film without in the opening;
forming a first convex electrode region on a surface of the inner cylindrical portion, and a second convex electrode region that is smaller than the first convex electrode region on a surface of the outer cylindrical portion;
forming a fourth insulating film over the first electrode; and
forming a second electrode over the fourth insulating film.

10. The method of manufacturing the multi-wall cylindrical capacitor according to claim 9, wherein the third insulating film is an oxide film, and the impurity ion is a phosphorus ion.

11. The method of manufacturing the multi-wall cylindrical capacitor according to claim 9, wherein the first impurity ion concentration is from 3E20 cm⁻³ to 4E20 cm⁻³, and the second impurity ion concentration is equal to or less than 1E20 cm⁻³.

12. The method of manufacturing the multi-wall cylindrical capacitor according to claim 9, wherein the first impurity ion concentration is from 4E20 cm⁻³ to 5E20 cm⁻³, and the second impurity ion concentration is equal to or less than 1E20 cm⁻³.

13. The method of manufacturing the multi-wall cylindrical capacitor according to claim 10, wherein the annealing is performed in a PH₄ atmosphere.

14. A multi-wall cylindrical capacitor, comprising:
a first electrode that includes an inner cylindrical portion having a first convex electrode region and an outer cylindrical portion having a second convex electrode region that is smaller than the first convex electrode region; and
an insulating film formed over the first electrode; and
a second electrode formed over the insulating film.

15. The multi-wall cylindrical capacitor according to claim 14, wherein the first and second convex electrode regions are a hemisphere structure.

16. A multi-wall cylindrical capacitor, comprising:
a first electrode that includes an inner cylindrical portion having a plurality of first convex electrode regions and an outer cylindrical portion having a plurality of second convex electrode regions which are smaller and more sparse than the plurality of first convex electrode regions; and
an insulating film formed over the first electrode; and
a second electrode formed over the insulating film.

17. The multi-wall cylindrical capacitor according to claim 16, wherein the plurality of first and second convex electrode regions are a hemisphere structure.
